(19) United States
(12) Patent Application Publication
(10) Pub. No.: US 2007/0247816 A1
(43) Pub. Date: Oct. 25, 2007

(54) STRUCTURE FOR A CHIP COOLING FAN

(76) Inventors: Hung-Teng Kuo, Shijr (TW); Yuan-Ching Chen, Shijr (TW)

Correspondence Address: LEONG C LEI, PMB # 1008, 1867 YGNACIO VALLEY ROAD, WALNUT CREEK, CA, 94598, US

(21) Appl. No.: 11/379,806

(22) Filed: Apr. 24, 2006

(51) Int. Cl. H05K 7/20

(52) U.S. Cl. 361/719

(57) ABSTRACT

The present invention relates to an improved structure for a chip cooling fan, in which the cooling fan assembly comprises a fan, magnets, bearing housing, bearing, printed circuit board, spindle and silicon steel-sheet winding and is characterized in: The said printed circuit board is laid outside the fan body assembly and connected to the fan by a lead. Thus, the innovative design of the present invention is capable to prevent from erosion and damage resulted from the said PCB which is caused by heat, magnetism shock as well as from both the bearing oil and dust absorbed by the fan assembly itself accordingly.

### BACKGROUND OF THE INVENTION

(a) Technical Field of the Invention

The present invention relates to an improved structure for a chip cooling fan, and particularly to a structural improvement on a chip cooling fan so as to separate its internal circuit board from the fan assembly.

(b) Description of the Prior Art

The chip cooler fans nowadays used for a notebook computers is laid closely to the central processing unit (CPU) that always exists in a high temperature state, therefore a cooling fan is necessary to be mounted above and kept on running in order to maintain the temperature stably. However, the heat is generated while the fan is running in addition to the potentiality in existence of shock and oozing oils resulted from the running bearings, hence the working environment is full of settled dust together with the surroundings of fan magnetism in a long period of time, which has made of the printed circuit board installed in-between the fan and chip to work under this dreadful condition all the time and hence resulting in a shorter service life with an inferior performance of such fan which is caused by a premature damage; and in light of all the defectives described above, we might say that an improvement is not only required necessarily but also very eagerly.

FIG. 1 is a schematic view showing an existing structure of the known fan and, wherein, the said chip cooler fan assembly 10 consists of the fan blades 11, a magnet 12, a bearing housing 13, a bearing 14, a printed circuit board 15, spindle 16 and silicon steel-sheet winding 17. A printed circuit board 15 (hereinafter referred as circuit board 15) is installed into a lower position of such fan assembly 10, generally in-between the fan blade 11 and the chip which needs to be cooled down. Therefore the said circuit board 15 must sustain the heat generated by such fan assembly 10 itself, the sight shock caused by a running bearing 14, both the oil stains and oil gas that might be oozing etc. While the working environment is full of settled dust together with the surroundings of fan magnetism of such fan assembly 10 in a long period of time, which will make the circuit board 15 installed in-between the fan 10 and chip to work under this dreadful condition all the time and hence resulting in a shorter service life with an inferior performance of such fan 10 which is caused by a premature damage; and in light of all the defectives described above, we might say that an improvement is not only required necessarily but also very eagerly.

### BRIEF DESCRIPTION OF THE DRAWINGS

FIG. 1 is a schematic view showing an existing structure of the known fan;

FIG. 2 is a schematic view showing the improved structure of a fan in accordance with the present invention.

### DETAILED DESCRIPTION OF THE PREFERRED EMBODIMENTS

The following descriptions are of exemplary embodiments only, and are not intended to limit the scope, applicability or configuration of the invention in any way. Rather, the following description provides a convenient illustration for implementing exemplary embodiments of the invention. Various changes to th described embodiments may be made in the function and arrangement of the elements described without departing from the scope of the invention as set forth in the appended claims.

With reference to FIG. 2, which is a schematic view showing the improved structure of a fan in accordance with the present invention, and wherein, the said chip cooler fan assembly 10 consists of the fan blades 11, a magnet 12, a bearing housing 13, a bearing 14, a printed circuit board 15, spindle 16 and silicon steel-sheet winding 17, and in which:

A printed circuit board 15 is laid outside the fan body assembly and connected to the fan 10 by a lead 18 accordingly.

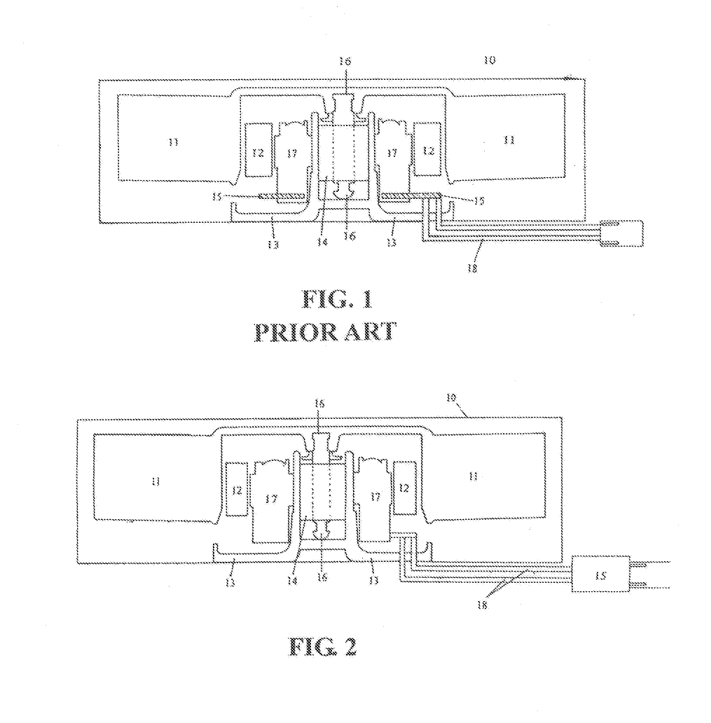

While with reference to both FIGS. 1 and 2, it shows that the said printed circuit board 15 is has been moved out of its original position individually and then connected with one end of the said lead 18 appropriately, which is far apart from the fan 10 and, hence, to provide the said fan assembly with a long service life by preventing it from any accidental damage.

The printed circuit board 15 of the present invention can be mounted at an appropriate position on any end of the side lead 18 according to realistic needs and, in this way it will be utilized much more convenient than usual. Thus, while having the improved structure of the present invention, it is not only capable to prevent from both the erosion and damage resulted from the internal PCB which is caused by the heat, magnetism, shock as well as from both the bearing oil and dust absorbed by the fan assembly itself accordingly.

It will be understood that each of the elements described above, or two or more together may also find a useful application in other types of methods differing from the type described above.

While certain novel features of this invention have been shown and described and are pointed out in the annexed claim, it is not intended to be limited to the details above, since it will be understood that various omissions, modifications, substitutions and changes in the forms and details of the device illustrated and in its operation can be made by those skilled in the art without departing in any way from the spirit of the present invention.

I claim:

1. An improved structure for a chip cooling fan, in which for cooling fan assembly comprises a fan, magnets, bearing housing, bearing, printed circuit board, spindle and silicon steel-sheet winding and is characterized in:
The said printed circuit board is laid outside the fan body assembly and connected to the fan by a lead.

2. The improved structure for a chip cooling fan as claimed in claim 1, which is characterized in that the printed circuit board is mounted externally on one side of the said fan assembly.
